(19) United States
(12) Patent Application Publication
(10) Pub. No.: US 2026/0013343 A1
(43) Pub. Date: Jan. 8, 2026

(54) Display Panel and Display Apparatus

(71) Applicant: HKC CORPORATION LIMITED, Shenzhen (CN)

(72) Inventors: Yang PU, Shenzhen (CN); Pei XU, Shenzhen (CN)

(73) Assignee: HKC CORPORATION LIMITED, Shenzhen (CN)

(21) Appl. No.: 19/258,723

(22) Filed: Jul. 2, 2025

(30) Foreign Application Priority Data
Jul. 2, 2024 (CN) 2024108774451

(51) Int. Cl. H10K 59/13; H10K 59/121; H10K 59/123; H10K 59/126; H10K 59/80; H10K 102/10

(52) U.S. Cl. CPC H10K 59/13; H10K 59/1213; H10K 59/123; H10K 59/126; H10K 59/873; H10K 2102/103

(57) ABSTRACT

Disclosed are a display panel and a display apparatus. The display panel includes a driving backplane, a light-emitting functional layer and a pixel definition layer. The driving backplane includes a main pixel driving unit, the pixel definition layer includes a plurality of pixel openings, and the light-emitting functional layer includes a plurality of main light-emitting units. At least part of the main light-emitting unit is located in the corresponding pixel opening, and the main light-emitting unit is electrically connected to the main pixel driving unit. The driving backplane further includes a compensation unit including a photosensitive assembly, a light-emitting compensation assembly and a sub pixel driving assembly, in which the photosensitive assembly is electrically connected to the main pixel driving unit. At least part of the light-emitting compensation assembly is located in the corresponding pixel opening, and the light-emitting compensation assembly is electrically connected to the sub-pixel driving assembly.

### CROSS-REFERENCE TO RELATED APPLICATIONS

The present disclosure claims all the benefits and priority of Chinese patent application No. 202410877445.1, filed on Jul. 2, 2024 before the China National Intellectual Property Administration of the People's Republic of China, entitled “Display Panel and Display Apparatus”, which is explicitly incorporated herein by reference in its entirety.

### FIELD

The present disclosure relates to the technical field of display, in particular to a display panel and a display apparatus.

### BACKGROUND

With continuous development of technology, the application scope of liquid crystal displays has gradually expanded. Liquid crystal displays are products such as LCD (Liquid Crystal Display) products, OLED (Organic Light-Emitting Diode) products, and Mini-LED products. OLED products have characteristics of high color saturation, high contrast, fast response speed, and slim and lightweight design, and are applied in various life scenes.

However, light-emitting materials in an OLED product have luminous efficiency gradually decreasing over the lighting time thereof. In particular, luminous efficiency of blue light-emitting materials decreases faster than that of red and green light-emitting materials. This will lead to an imbalance in the luminance of the red, green and blue colors during follow-up use of the OLED product, resulting in color shift and affecting the display effect of the OLED product.

### SUMMARY

A display panel and a display apparatus are provided in the present disclosure, which can reduce color shift, meet display requirements and improve market competitiveness.

In a first aspect, a display panel is provided in the present disclosure, including a driving backplane, and a light-emitting functional layer and a pixel definition layer that are sequentially formed on the driving backplane. The driving backplane includes a main pixel driving unit, the pixel definition layer includes a plurality of pixel openings, the light-emitting functional layer includes a plurality of main light-emitting units, where at least part of the main light-emitting unit is located in the corresponding pixel opening, and the main light-emitting unit is electrically connected to the main pixel driving unit;
the driving backplane further includes a compensation unit, the compensation unit includes a photosensitive assembly, a light-emitting compensation assembly and a sub pixel driving assembly, and the photosensitive assembly is electrically connected to the main pixel driving unit; and
at least part of the light-emitting compensation assembly is located in the corresponding pixel opening, and the light-emitting compensation assembly is electrically connected to the sub-pixel driving assembly; when the sub pixel driving assembly drives the light-emitting compensation assembly to emit light, light from the light-emitting compensation assembly irradiates the photosensitive assembly to adjust a resistance of the photosensitive assembly.

In a possible embodiment, the photosensitive assembly includes a photoresistor, a first drain, a first active layer and a first source; and
each of the first drain and the first source is formed on the first active layer, the first drain is electrically connected to the photoresistor, and the photoresistor is electrically connected to the main pixel driving unit.

In a possible embodiment, the main pixel driving unit includes a third drain, a third active layer and a third source, each of the third drain and the third source is formed on the third active layer, and the third drain is electrically connected to the photoresistor.

In a possible embodiment, the sub pixel electrode layer is an anode layer made of indium tin oxide.

In a possible embodiment, the sub pixel electrode layer is disposed on a side of the auxiliary light-emitting layer close to the driving backplane, and the auxiliary light-emitting layer is connected to the sub pixel driving assembly through the sub pixel electrode layer.

In a possible embodiment, the light-emitting compensation assembly includes an auxiliary light-emitting layer and a sub pixel electrode layer, the auxiliary light-emitting layer is located in the corresponding pixel opening, at least part of the sub pixel electrode layer is located in the corresponding pixel opening to be electrically connected to the auxiliary light-emitting layer, and the sub pixel electrode layer is electrically connected to the sub pixel driving assembly.

In a possible embodiment, a projection area of the auxiliary light-emitting layer on the driving backplane at least partially overlaps a projection area of the photoresistor on the driving backplane.

In a possible embodiment, the sub pixel driving assembly includes a second drain, a second active layer and a second source, each of the second drain and the second source is disposed on the second active layer, and the second drain is electrically connected to the sub pixel electrode layer.

In a possible embodiment, the display panel further includes a light shielding layer disposed above the light-emitting compensation assembly.

In a possible embodiment, the display panel further includes an encapsulation layer which covers the light-emitting functional layer and the pixel definition layer, and the light shielding layer is disposed on a side of the encapsulation layer away from the driving backplane.

In a possible embodiment, the driving backplane includes a base substrate, a buffer layer, a gate driving layer and a planarization layer which are stacked in sequence;
each of the compensation unit, the main pixel driving unit and the sub pixel driving assembly is formed in the gate driving layer;
each of the compensation unit, the main pixel driving unit and the sub pixel driving assembly is connected to the buffer layer; and
the planarization layer covers the compensation unit, the main pixel driving unit and the sub pixel driving assembly.

In a possible embodiment, the buffer layer is formed on the base substrate and covers the base substrate, and an orthographic projection area of the buffer layer is the same as that of the base substrate.

In a possible embodiment, the main pixel anode layer is disposed on the planarization layer.

In a possible embodiment, the gate driving layer is configured to output the same gate signal, so as to control the main pixel driving unit and the compensation unit to be turned on or turned off simultaneously.

In a second aspect, a display apparatus is provided in the present disclosure, including a power supply module and the display panel as described in the first aspect of the disclosure, in which the power supply module is electrically connected to the display panel.

The above technical solutions provided in the embodiments of the present disclosure have the following advantages compared to the related art:
according to the display panel and the display apparatus provided in the embodiments of the present disclosure, the compensation unit is used to connect a compensation signal to the main pixel driving unit, and a resistance of the photosensitive assembly in the compensation unit is affected by the light-emitting compensation assembly, thereby changing luminance of the main light-emitting unit. As the luminance of the light-emitting compensation assembly is attenuated over time, the luminance of the light received by the photosensitive assembly decreases, resulting in an increase in the resistance. Therefore, less current flows to the compensation unit side, while more current flows to the main pixel driving unit side of the display panel, thereby reducing an effect on the main light-emitting unit. In this way, the luminance of the main light-emitting unit is larger, thereby compensating for the luminance attenuation due to a lifespan, effectively improving a display state of the main light-emitting unit, and avoiding the color shift of the display panel.

### BRIEF DESCRIPTION OF DRAWINGS

The accompanying drawings here, which are incorporated in the specification and constitute a part of the specification, show embodiments according to the present disclosure and serve to explain principles of the disclosure together with the specification.

In order to more clearly illustrate embodiments of the disclosure or technical solutions in the related art, drawings that need to be used in description of the embodiments or the related art are briefly introduced below, and it will be apparent to those of ordinary skill in the art that other drawings may be obtained based on these drawings without inventive work.

One or more embodiments are illustrated by way of example in the figures of the accompanying drawings, which do not constitute a limitation on the embodiments, and elements in the drawings having the same reference numerals are designated as like elements, and the figures in the drawings are not to scale unless otherwise specified.

FIG. 1 is a schematic cross-sectional view of a display panel provided in an embodiment of the present disclosure;

FIG. 2 is a schematic cross-sectional view of a display panel provided in an embodiment of the present disclosure;

FIG. 3 is a schematic diagram showing a circuit structure of a display panel provided in an embodiment of the present disclosure; and

FIG. 4 is a block diagram of a display apparatus provided in an embodiment of the present disclosure.

### DESCRIPTION OF REFERENCE NUMERALS

1—driving backplane; 11—main pixel driving unit; 111—third drain; 112—third active layer; 113—third source; 12—base substrate; 13—buffer layer; 14—gate driving layer; 141—gate insulating layer; 142—interlayer insulating dielectric layer; 143—gate; 15—planarization layer; 16—main pixel anode layer; 17—compensation unit; 171—photosensitive assembly; 1711—photoresistor; 1712—first drain; 1713—first active layer; 1714—first source; 172—light-emitting compensation assembly; 1721—auxiliary light-emitting layer; 1722—sub pixel electrode layer; 173—sub pixel driving assembly; 1731—second drain; 1732—second active layer; 1733—second source; 2—light-emitting functional layer; 21—main light-emitting unit; 3—pixel definition layer; 31—pixel opening; 4—light shielding layer; 5—encapsulation layer; 6—power supply module; A—display panel.

### DETAILED DESCRIPTION

In order to make objects, technical solutions, and advantages of embodiments of the disclosure clearer, the technical solutions in the embodiments of the disclosure will be clearly and fully described in combination with the accompanying drawings in the embodiments of the disclosure. Obviously, the embodiments to be described are part of embodiments but not all embodiments of the disclosure. Based on the embodiments in the disclosure, all other embodiments obtained by those of ordinary skill in the art without inventive work shall fall within the scope of the disclosure.

Many different embodiments or examples are disclosed below to realize different structures of the disclosure. In order to simplify the disclosure, components and arrangements of specific examples are described below. Of course, they are only examples and are not intended to limit the disclosure. Furthermore, the present disclosure may repeat reference numerals and/or letters in different examples. The repetition is for simplicity and clarity, and in itself does not indicate the relationship between the various embodiments and/or arrangements discussed.

For the convenience of description, spatial relationship terms can be used herein to describe the relative positional relationship or movement of one element or feature relative to another element or feature as shown in the drawings, such as “inside”, “outside”, “inner”, “outer”, “under”, “below”, “on”, “above”, “front” and “back”. This spatial relationship term is intended to include different orientations of the device in use or operation other than orientations depicted in the drawings. For example, if the device in the drawings has a position turnover, a posture change or a movement state change, these directional indications will change accordingly, for example: Elements described as “under or below other elements or features” will be subsequently oriented as “on or over other elements or features”. Thus, the exemplary term “below” may include both orientations of above and below. The device may be otherwise oriented (rotated by 90 degrees or in other directions), and the spatial relationship terms used herein are interpreted accordingly.

In order to solve the technical problem that luminance of red, green and blue colors of the display panel is imbalanced over time, and luminous efficiency of blue is particularly low, resulting in color shift and affecting the display effect of the OLED product, the disclosure provides a display panel. The compensation unit is used to connect a compensation signal to the main pixel driving unit, and a resistance of the photosensitive assembly in the compensation unit is affected by the light-emitting compensation assembly, thereby changing luminance of the main light-emitting unit. As the luminance of the light-emitting compensation assembly is attenuated over time, the luminance of the light received by the photosensitive assembly decreases, resulting in an increase in the resistance. Therefore, less current flows to the compensation unit side, while more current flows to the main pixel driving unit side of the display panel, thereby reducing an effect on the main light-emitting unit. In this way, the luminance of the main light-emitting unit is larger, thereby compensating for the luminance attenuation due to a lifespan, effectively improving a display state of the main light-emitting unit, and avoiding the color shift of the display panel.

### First Embodiment

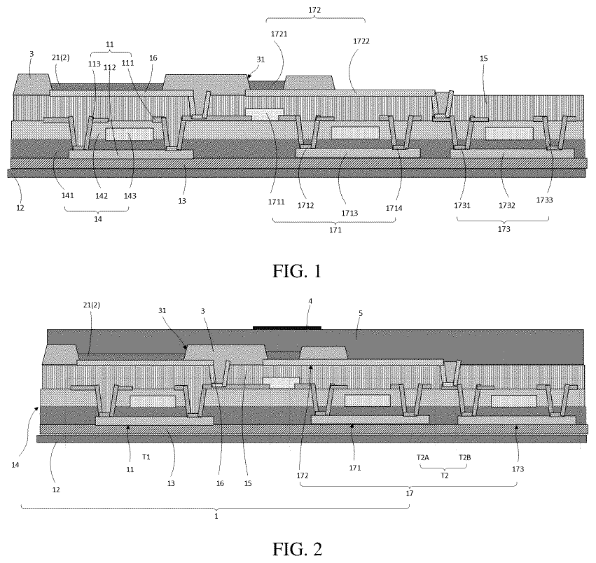

FIG. 1 is a schematic cross-sectional view of a display panel provided in an embodiment of the present disclosure. FIG. 2 is a schematic cross-sectional view of a display panel provided in an embodiment of the present disclosure.

Embodiments of the present disclosure provide a display panel, such as an OLED display panel, which may be applied to a display apparatus. The display apparatus may be portable equipment such as a mobile phone, or a computer, etc.

The display panel includes a driving backplane 1, a light-emitting functional layer 2 and a pixel definition layer (PDL) 3. The light-emitting functional layer 2 is formed on the driving backplane 1, and the pixel definition layer 3 is formed on a side of the light-emitting functional layer 2 away from the driving backplane 1.

The driving backplane 1 includes a main pixel driving unit 11. The pixel definition layer 3 includes a plurality of pixel openings 31. For example, the pixel openings 31 are arranged in an array. The light-emitting functional layer 2 includes a plurality of main light-emitting units 21. Each of the main light-emitting units 21 includes, for example, a red light-emitting unit, a green light-emitting unit and a blue light-emitting unit, so as to meet the display requirements of the display panel.

It should be noted that only one main light-emitting unit 21 is shown in the figures, however, this does not constitute a limitation to the present disclosure. The main light-emitting unit 21 is made of, for example, a fluorescent material, a phosphorescent material or a thermally activated delayed fluorescence (TADF) material, so as to achieve a good color rendering effect.

At least part of the main light-emitting unit 21 is located in a corresponding pixel opening 31. The pixel definition layer 3 is configured to support or separate the main light-emitting units 21, preventing mutual interference between adjacent main light-emitting units 21 from affecting the normal display of the display panel.

The main light-emitting unit 21 is electrically connected to the main pixel driving unit 11. The driving backplane 1 is made of, for example, low temperature polysilicon (LTPS), which may include, for example, thin-film transistors (TFTs). The use of the polysilicon liquid crystal material can make the thin-film transistors thinner and smaller, with lower power consumption.

It is understandable that the above-mentioned driving backplane 1 may also be made of a semiconductor such as amorphous silicon, monocrystalline silicon, or a metal oxide, depending on the actual situation.

The thin-film transistors are configured to be electrically connected to the main light-emitting unit 21. The thin-film transistors correspond to pixel circuits that controls lighting of the main light-emitting unit 21. Each of the main light-emitting units 21 corresponds to one of the pixel circuits, and lighting and the extinguishing of the main light-emitting unit 21 is controlled by controlling the pixel circuit. Each of the pixel circuits at least includes a TFT structure and a capacitor structure. The TFT structure mainly includes a gate layer, an active layer, a source, a drain, and buffer layers and dielectric layers disposed between the above layers. An exemplary description is provided below to facilitate a further understanding of configurations of the layers.

In some examples, the driving backplane 1 includes, for example, a base substrate 12, a buffer layer 13, a gate driving layer 14 and a planarization layer 15 which are stacked in sequence.

The base substrate 12 is, for example, a rigid substrate made of glass, or the base substrate 12 may be a flexible substrate made of a material such as polyimide (PI) to form a transparent base substrate 12. The display panel of the present disclosure is not limited to a rigid non-bendable display panel, and may be a flexible bendable display panel.

The buffer layer 13 is formed on the base substrate 12 and covers the base substrate 12, and an orthographic projection area of the buffer layer 13 is the same as that of the base substrate 12, thereby protecting the upper and lower sides. The buffer layer 13 is, for example, a single-layer film of amorphous silicon oxide (SiOx) or silicon nitride (SiNx).

The gate driving layer 14 is formed on the buffer layer 13, and the gate driving layer 14 is powered on to turn on various devices connected thereto, which allows a current to flow in the main pixel driving unit 11, thereby achieving a power-on effect and meeting power-on requirements of the display panel.

For example, the gate driving layer 14 includes a gate insulating (GI) layer 141, an interlayer insulating dielectric (ILD) layer 142 and a plurality of gates 143. The gate insulating layer 141 is formed on the buffer layer 13, and a plurality of the gates 143 are arranged on the buffer layer 13 at intervals. The interlayer insulating dielectric layer 142 is formed on the gate insulating layer 141 and covers all the gates 143 to separate a conductive material on an upper side from a conductive material on a lower side, so as to ensure normal operation of various devices. The gate insulating layer 141 is, for example, a single-layer film of amorphous silicon oxide (SiOx) or silicon nitride (SiNx). The gate 143 is made of, for example, metal materials such as aluminum (Al), copper (Cu) and molybdenum (Mo), which have good conductivity. The interlayer insulating dielectric layer 142 is, for example, a single-layer film of amorphous silicon oxide (SiOx) or silicon nitride (SiNx).

The main pixel driving unit 11 is formed in the gate driving layer 14, and the gate driving layer 14 is connected to the buffer layer 13. The planarization layer 15 is deposited on the gate driving layer 14 and covers at least part of the structure of the main pixel driving unit 11. The planarization layer 15 has a smooth characteristic and can ensure flatness of the film structure. The planarization (PLN) layer 15 is made of, for example, an organic material polyimide (PI) and thus has good electrical insulation, wear resistance and physical and mechanical properties.

A main pixel anode layer 16 is formed on the planarization layer 15. The main pixel anode layer 16 is used to electrically connect the main light-emitting unit 21 with the main pixel driving unit 11, so as to realize the power on of the light-emitting devices. The main pixel anode layer 16 is, for example, silver (Ag) or indium tin oxide (ITO) deposited on the planarization layer 15. The planarization layer 15 has a smooth characteristic, and the main pixel anode layer 16 which is also smooth is disposed on the planarization layer 15. Accordingly, the main pixel anode layer 16 made in an entire surface has a small surface difference, so that more light can be reflected by or transmitted by the main pixel anode layer 16, and thus the luminous efficiency is high.

It should be noted that during manufacturing of the driving backplane 1 in the present disclosure, the various film structures may be formed by a deposition process, a film forming process, a photolithography process, an etching process, and the like. The specific process flow and process method will not be described in detail here, as long as they can achieve their corresponding functions.

In this embodiment, the driving backplane 1 further includes a compensation unit 17, which includes a photosensitive assembly 171, a light-emitting compensation assembly 172 and a sub pixel driving assembly 173. The photosensitive assembly 171 and the sub pixel driving assembly 173 are disposed on the driving substrate 1 in a manner similar to or the same as the manner in which the main pixel driving unit 11 is disposed on the driving substrate 1. For example, each of the photosensitive assembly 171 and the sub pixel driving assembly 173 is formed in the gate driving layer 14, and each of the photosensitive assembly 171 and the sub pixel driving assembly 173 is connected to the buffer layer 13, and the planarization layer 15 covers the photosensitive assembly 171 and the sub pixel driving assembly 173.

The photosensitive assembly 171 is electrically connected to the main pixel driving unit 11, so as to control a resistance of the photosensitive assembly 171, thereby changing a current value of the display panel on a side of the main pixel driving unit 11 and adjusting the luminance of the display panel.

In some examples, the photosensitive assembly 171 includes a photoresistor 1711, a first drain 1712, a first active layer 1713 and a first source 1714. Each of the first drain 1712 and the first source 1714 is formed on the first active layer 1713. The first drain 1712 is electrically connected to the photoresistor 1711, and the photoresistor 1711 is electrically connected to the main pixel driving unit 11.

The current enters from the first source 1714, flows through the first active layer 1713 and the first drain 1712 in sequence, and then enters the photoresistor 1711. The photoresistor 1711 may be made of a material such as cadmium sulfide (CdS), aluminum sulfide (AIS), lead sulfide (PbS), bismuth sulfide or selenium sulfide. The first drain 1712 may be made of a metal material such as aluminum (Al), copper (Cu) or molybdenum (Mo). The first source 1714 may be made of a metal material such as aluminum (Al), copper (Cu) or molybdenum (Mo). The first active layer 1713 may be a semiconductor layer formed of a polycrystalline silicon (Poly-Si) film.

At least part of the light-emitting compensation assembly 172 is located in the corresponding pixel opening 31, and the light-emitting compensation assembly 172 is electrically connected to the sub pixel driving assembly 173, so that the sub pixel driving assembly 173 can drive the light-emitting compensation assembly 172 to emit light. The color of light of the light-emitting compensation assembly 172 is mainly based on actual situations and is not limited here.

The light-emitting compensation assembly 172 includes an auxiliary light-emitting layer 1721 and a sub pixel electrode layer 1722. The auxiliary light-emitting layer 1721 is located in the corresponding pixel opening 31, at least part of the sub pixel electrode layer 1722 is located in the corresponding pixel opening 31 and is electrically connected to the auxiliary light-emitting layer 1721, and the sub pixel electrode layer 1722 is electrically connected to the sub pixel driving assembly 173.

The auxiliary light-emitting layer 1721 is made of, for example, a fluorescent material, a phosphorescent material or a thermally activated delayed fluorescence (TADF) material, so as to achieve a good color rendering effect. The color of the light emitted by the auxiliary light-emitting layer 1721 depends on the actual situation. The sub pixel electrode layer 1722 is, for example, an anode layer, which is made of indium tin oxide (ITO) and is transparent, so that the light from the auxiliary light-emitting layer 1721 can pass through the sub pixel electrode layer 1722 and be transmitted to the photoresistor 1711 to change a resistance of the photoresistor 1711. The sub pixel electrode layer 1722 has good transmittance and thus can improve an overall optical performance. The sub pixel electrode layer 1722 has stable properties and is less prone to oxidation, corrosion and the like, which effectively extends a service life thereof.

A projection area of the auxiliary light-emitting layer 1721 on the driving backplane 1 at least partially overlaps a projection area of the photoresistor 1711 on the driving backplane 1, so as to ensure that the light from the auxiliary light-emitting layer 1721 can irradiate the photoresistor 1711.

In this embodiment, the sub pixel electrode layer 1722 is disposed on a side of the auxiliary light-emitting layer 1721 close to the driving backplane 1, and the auxiliary light-emitting layer 1721 is connected to the sub pixel driving assembly 173 through the sub pixel electrode layer 1722 to form a complete current path, thereby realizing driving of the auxiliary light-emitting layer 1721.

In some examples, the sub pixel driving assembly 173 includes, for example, a second drain 1731, a second active layer 1732 and a second source 1733. Each of the second drain 1731 and the second source 1733 is disposed on the second active layer 1732, and the sub pixel electrode layer 1722 is electrically connected to the second drain 1731. The second drain 1731 may be made of metal materials such as aluminum (Al), copper (Cu) and molybdenum (Mo). The second source 1733 may be made of metal materials such as aluminum (Al), copper (Cu) and molybdenum (Mo). The second source 1733 may be a semiconductor layer formed of a polycrystalline silicon (Poly-Si) film.

When the sub pixel driving assembly 173 drives the light-emitting compensation assembly 172 to emit light, the light from the light-emitting compensation assembly 172 can irradiate the photoresistor 1711, so as to adjust the resistance of the photoresistor 1711. As the luminance of the light-emitting compensation assembly 172 decreases, the resistance of the photoresistor 1711 increases. Therefore, a current on the side of the photoresistor 1711 is small, so that a current flowing to the side of the main pixel driving unit 11 of the display panel is large, and the luminance of the main light-emitting unit 21 is higher, thereby compensating for luminance attenuation due to lifespan and avoiding color shift.

It should be noted that a gate 143 is disposed between the second drain 1731 and the second source 1733 to control turning-on or turning-off of the sub pixel driving assembly 173. Likewise, a gate 143 is disposed between the first drain 1712 and the first source 1714 to control turning-on or turning-off of the photosensitive assembly 171.

In addition, it should be noted that the main pixel driving unit 11 may include, for example, a third drain 111, a third active layer 112 and a third source 113. Each of the third drain 111 and the third source 113 is formed on the third active layer 112, and the third drain 111 is electrically connected to the photoresistor 1711. The third drain 111 may be made of metal materials such as aluminum (Al), copper (Cu) and molybdenum (Mo). The third source 113 may be made of metal materials such as aluminum (Al), copper (Cu) and molybdenum (Mo). The third active layer 112 may be a semiconductor layer formed of a polycrystalline silicon (Poly-Si) film. A gate 143 is disposed between the third drain 111 and the third source 113 to control turning-on or turning-off of the main pixel driving unit 11.

The display panel proposed in this embodiment uses the compensation unit to connect a compensation signal to the main pixel anode layer in the main pixel driving unit, and the compensation unit and the main pixel driving unit are turned on or turned off simultaneously. That is, the compensation unit is turned on when the main light-emitting unit emits light, and the compensation unit is turned off when the main light-emitting unit does not emit light. The resistance of the photoresistor in the compensation unit is affected by an auxiliary light-emitting layer, thereby changing the luminance of the main light-emitting unit. As the luminance of the auxiliary light-emitting layer is attenuated over time, the luminance of the light received by the photosensitive assembly decreases, resulting in an increase in the resistance. Therefore, less current flows to the compensation unit side, while more current flows to the main pixel driving unit side of the display panel, thereby reducing an effect on the main light-emitting unit. In this way, the luminance of the main light-emitting unit is larger, thereby compensating for the luminance attenuation due to a lifespan, effectively improving a display state of the main light-emitting unit, and avoiding the color shift of the display panel.

### Second Embodiment

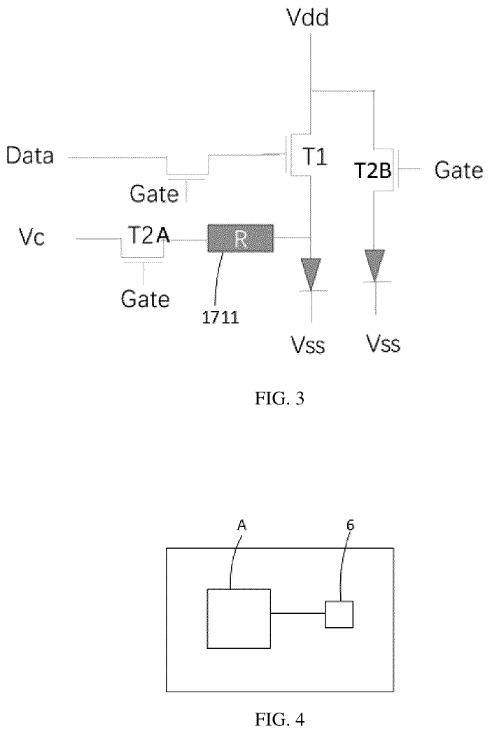

FIG. 1 is a schematic cross-sectional view of a display panel provided in an embodiment of the present disclosure. FIG. 2 is a schematic cross-sectional view of a display panel provided in an embodiment of the present disclosure. FIG. 3 is a schematic diagram showing a circuit structure of a display panel provided in an embodiment of the present disclosure.

A second embodiment of the present disclosure further provides a display panel. In this embodiment, a luminance compensation principle of the display panel is explained in detail. Taking FIG. 2 as an example, an area where the main pixel driving unit 11 is located is defined as a T1 area, and an area where the compensation unit 17 is located is defined as a T2 area. The T2 area may include a T2A area where the photosensitive assembly 171 is located, and a T2B area where the sub pixel driving assembly 173 is located.

When the display panel is in a light-emitting stage, a data signal of a data signal terminal (Data) controls the main pixel driving unit 11 in the T1 area to be turned on or turned off since the gate 143 in the T1 area outputs a gate signal (Gate). Here, the data signal terminal is used to control the light intensity in the T1 area.

The gate 143 in the T2B area outputs the gate signal (Gate) to control the sub pixel driving assembly 173 in the T2B area to be turned on or turned off. The gate 143 in the T2A area outputs the gate signal (Gate) to control the photosensitive assembly 171 in the T2A area to be turned on or turned off.

A voltage of a power supply terminal (Vdd) is input to the main pixel driving unit 11 in the T1 area and the sub pixel driving assembly 173 in the T2B area, and then transmitted to a power ground terminal (Vss), so as to achieve their respective light emission.

A connection signal of the photosensitive assembly 171 in the T2A area is a compensation signal Vc, and Vc is a negative voltage (−0.5 V to −10 V), which is connected to the main pixel driving unit 11 in the T1 area through the photosensitive assembly 171 and then transmitted to a power ground terminal (Vss).

During the light-emitting stage mentioned above, a current flows through the display panel. When luminance of the light received by the photoresistor 1711 in the photosensitive assembly 171 decreases, the resistance of the photoresistor 1711 increases, and thus a current flowing through the photoresistor 1711 decreases, so that a current used to drive the main pixel driving unit 11 increases. Accordingly, the luminance of the main light-emitting unit 21 in the T1 area increases, which effectively compensates for the luminance attenuation due to the lifespan. That is, an effect of the photosensitive assembly 171 on the light emission of the display panel decreases.

The light-emitting compensation assembly 172 in the T2B area undergoes device aging and loss over time, causing a gradual decrease in the luminance of the light-emitting compensation assembly 172. Since the luminance of the light emitted by the light-emitting compensation assembly 172 decreases, the luminance of the light received by the photoresistor 1711 decreases, and the resistance of the photoresistor 1711 increases. The resistance of the photoresistor 1711 is inversely proportional to the luminance of the light received by the photoresistor 1711. The larger the luminance of the light received by the photoresistor 1711, the smaller the resistance thereof. The lower the luminance of the light received by the photoresistor 1711, the larger the resistance thereof.

The gate driving layer 14 in the T1 area and the T2 area may control the gate 143 to output the same gate signal, so as to control the main pixel driving unit 11 and the sub pixel driving assembly 173 to be turned on or turned off simultaneously, which achieves simultaneous lighting or extinguishing of the main light-emitting unit 21 and the light-emitting compensation assembly 172, and avoids changes in the resistance of the photoresistor 1711 caused by luminance changes of the display screen in the T2B area, thereby ensuring that the resistance of the photoresistor 1711 is only affected by the luminance attenuation caused by an increase of lighting time of the light-emitting compensation assembly 172 in the T2B.

It should be noted that when lighted, the above light-emitting compensation assembly 172 always operates at a maximum luminance. The maximum luminance is realized by providing the power supply terminal (Vdd) with a consistent maximum voltage, which is an ideal state. However, in practice, the luminance may have a problem such as loss, and may not be the maximum luminance, but rather a large luminance under the drive of the power supply terminal (Vdd). In other words, the driving voltage of the power supply terminal (Vdd) always maintains the maximum voltage provided by the display panel.

The display panel proposed in this embodiment is connected to the main pixel anode layer through the compensation signal Vc and the compensation unit, controls the main pixel driving unit and the compensation unit to be turned on or turned off synchronously, thereby realizing simultaneous lighting or extinguishing of the light-emitting compensation assembly and the main light-emitting unit, and avoids changes in the resistance of the photoresistor caused by luminance changes of the display screen in the T2B area, so that the resistance of the photoresistor is only affected by the luminance attenuation caused by an increase of lighting time of the light-emitting compensation assembly.

During use of the panel, the luminance of the light-emitting compensation assembly gradually decreases over time, so that the resistance of the photoresistor gradually increases. In this way, the effect of the compensation signal on light emission in the T1 area decreases, thereby effectively improving the luminance of the display panel and achieving the effect of compensation for the luminance attenuation. Additionally, as the luminance attenuation of blue light is generally faster, greater luminance compensation is applied to the blue light, which effectively reduces the color shift.

### Third Embodiment

FIG. 1 is a schematic cross-sectional view of a display panel provided in an embodiment of the present disclosure. FIG. 2 is a schematic cross-sectional view of a display panel provided in an embodiment of the present disclosure.

The third embodiment of the present disclosure further provides a display panel, which has the same or similar structure as the display panel provided in the first embodiment, except that the display panel in this embodiment further includes a light shielding layer 4 disposed above the light-emitting compensation assembly 172.

A projection area of the light shielding layer 4 on the driving backplane 1 is larger than a projection area of the auxiliary light-emitting layer 1721 in the light-emitting compensation assembly 172 on the driving backplane 1, so as to ensure that the light shielding layer 4 can completely shield the light from the auxiliary light-emitting layer 1721. Accordingly, the light from the auxiliary light-emitting layer 1721 will not be emitted out of the display panel, thereby avoiding affecting the normal display of the display panel.

The light shielding layer 4 is made of materials with a light shielding function, such as chromium (Cr), chromium oxide (CrOx), and black resin.

In this embodiment, the display panel further includes an encapsulation layer 5, which covers the light-emitting functional layer 2 and the pixel definition layer 3. The light shielding layer 4 is disposed on a side of the encapsulation layer 5 away from the driving backplane 1. The encapsulation layer 5 can prevent water and oxygen from invading the main light-emitting unit 21 and the auxiliary light-emitting layer 1721 which are formed of organic light-emitting materials, thereby avoiding failure.

The light-shielding layer proposed in this embodiment can shield the auxiliary light-emitting layer to ensure that light therefrom will not be emitted out of the display panel, thereby avoiding affecting the normal display of the display panel.

### Fourth Embodiment

FIG. 4 shows a block diagram of a display apparatus provided in an embodiment of the present disclosure.

A fourth embodiment of the present disclosure further provides a display apparatus, which includes a power supply module 6 and the display panel A as described in any one of the first embodiment, the second embodiment and the third embodiment. The power supply module is electrically connected to the display panel to meet requirements and functions of the display apparatus.

It should be understood that the terms used herein are only for the purpose of describing specific exemplary embodiments and are not intended to be limiting. Unless the context clearly indicates otherwise, the singular forms “a”, “an” and “the” as used herein can also mean including plural forms. The terms “include”, “including”, “comprise” and “comprising” are inclusive and thus indicate the presence of features, steps, operations, elements and/or components described, but do not exclude the presence or addition of one or more other features, steps, operations, elements, components, and/or combinations thereof. The method steps, procedures, and operations described herein are not interpreted as necessarily requiring them to be executed in the specific order described, unless the execution order is explicitly indicated. It should also be understood that additional or alternative steps may be used.

Although a plurality of elements, components, regions, layers and/or sections can be described herein with the terms first, second, third, and the like, they should not be limited by these terms. These terms may be only configured to distinguish one element, component, region, layer or section from another ones. Terms such as “first” and “second” and other numerical terms do not imply sequence or order when used herein unless clearly indicated in the context. Accordingly, the first element, component, region, layer or section discussed below may be referred to as a second element, component, region, layer or section without departing from teachings of the exemplary embodiments.

The above is only description of embodiments of the present disclosure to enable those skilled in the art to understand or implement the present disclosure. Various modifications to these embodiments will be apparent to those skilled in the art, and general principles defined herein may be implemented in other embodiments without departing from the spirit or scope of the present disclosure. Thus, the present disclosure is not limited to the embodiments described herein, but shall conform to the widest scope consistent with the principles and novelty applied for herein.

What is claimed is:

1. A display panel comprising a driving backplane, and a light-emitting functional layer and a pixel definition layer that are sequentially formed on the driving backplane, wherein the driving backplane comprises a main pixel driving unit, the pixel definition layer comprises a plurality of pixel openings, the light-emitting functional layer comprises a plurality of main light-emitting units, at least part of the main light-emitting unit is located in the corresponding pixel opening, and the main light-emitting unit is electrically connected to the main pixel driving unit;
the driving backplane further comprises a compensation unit, the compensation unit comprises a photosensitive assembly, a light-emitting compensation assembly and a sub pixel driving assembly, and the photosensitive assembly is electrically connected to the main pixel driving unit; and
at least part of the light-emitting compensation assembly is located in the corresponding pixel opening, and the light-emitting compensation assembly is electrically connected to the sub-pixel driving assembly; when the sub pixel driving assembly drives the light-emitting compensation assembly to emit light, light from the light-emitting compensation assembly irradiates the photosensitive assembly to adjust a resistance of the photosensitive assembly.

2. The display panel according to claim 1, wherein the photosensitive assembly includes a photoresistor, a first drain, a first active layer and a first source; and
each of the first drain and the first source is formed on the first active layer, the first drain is electrically connected to the photoresistor, and the photoresistor is electrically connected to the main pixel driving unit.

3. The display panel according to claim 2, wherein the main pixel driving unit includes a third drain, a third active layer and a third source, each of the third drain and the third source is formed on the third active layer, and the third drain is electrically connected to the photoresistor.

4. The display panel according to claim 2, wherein the light-emitting compensation assembly includes an auxiliary light-emitting layer and a sub pixel electrode layer, the auxiliary light-emitting layer is located in the corresponding pixel opening, at least part of the sub pixel electrode layer is located in the corresponding pixel opening to be electrically connected to the auxiliary light-emitting layer, and the sub pixel electrode layer is electrically connected to the sub pixel driving assembly.

5. The display panel according to claim 4, wherein the sub pixel electrode layer is an anode layer made of indium tin oxide.

6. The display panel according to claim 4, wherein the sub pixel electrode layer is disposed on a side of the auxiliary light-emitting layer close to the driving backplane, and the auxiliary light-emitting layer is connected to the sub pixel driving assembly through the sub pixel electrode layer.

7. The display panel according to claim 4, wherein a projection area of the auxiliary light-emitting layer on the driving backplane at least partially overlaps a projection area of the photoresistor on the driving backplane.

8. The display panel according to claim 4, wherein the sub pixel driving assembly includes a second drain, a second active layer and a second source, each of the second drain and the second source is disposed on the second active layer, and the second drain is electrically connected to the sub pixel electrode layer.

9. The display panel according to claim 1, further including a light shielding layer disposed above the light-emitting compensation assembly.

10. The display panel according to claim 9, further including an encapsulation layer which covers the light-emitting functional layer and the pixel definition layer, wherein the light shielding layer is disposed on a side of the encapsulation layer away from the driving backplane.

11. The display panel according to claim 1, wherein the driving backplane includes a base substrate, a buffer layer, a gate driving layer and a planarization layer which are stacked in sequence;
each of the compensation unit, the main pixel driving unit and the sub pixel driving assembly is formed in the gate driving layer;
each of the compensation unit, the main pixel driving unit and the sub pixel driving assembly is connected to the buffer layer; and
the planarization layer covers the compensation unit, the main pixel driving unit and the sub pixel driving assembly.

12. The display panel according to claim 11, wherein the buffer layer is formed on the base substrate and covers the base substrate, and an orthographic projection area of the buffer layer is the same as that of the base substrate.

13. The display panel according to claim 11, wherein the main pixel anode layer is disposed on the planarization layer.

14. The display panel according to claim 11, wherein the gate driving layer is configured to output the same gate signal, so as to control the main pixel driving unit and the compensation unit to be turned on or turned off simultaneously.

15. A display apparatus including a power supply module and a display panel, wherein
the power supply module is electrically connected to the display panel; and
the display panel comprises a driving backplane, and a light-emitting functional layer and a pixel definition layer that are sequentially formed on the driving backplane, wherein the driving backplane comprises a main pixel driving unit, the pixel definition layer comprises a plurality of pixel openings, the light-emitting functional layer comprises a plurality of main light-emitting units, at least part of the main light-emitting unit is located in the corresponding pixel opening, and the main light-emitting unit is electrically connected to the main pixel driving unit;
the driving backplane further comprises a compensation unit, the compensation unit comprises a photosensitive assembly, a light-emitting compensation assembly and a sub pixel driving assembly, and the photosensitive assembly is electrically connected to the main pixel driving unit; and
at least part of the light-emitting compensation assembly is located in the corresponding pixel opening, and the light-emitting compensation assembly is electrically connected to the sub-pixel driving assembly; when the sub pixel driving assembly drives the light-emitting compensation assembly to emit light, light from the light-emitting compensation assembly irradiates the photosensitive assembly to adjust a resistance of the photosensitive assembly.
